(19) United States
(12) Patent Application Publication
(10) Pub. No.: US 2007/0281383 A1
(43) Pub. Date: Dec. 6, 2007

(54) METHOD OF MANUFACTURING SEMICONDUCTOR MULTILAYER STRUCTURE

(75) Inventors: Chikara WATATANI, Tokyo (JP); Toru OTA, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 11/558,515

(22) Filed: Nov. 10, 2006

(30) Foreign Application Priority Data
May 30, 2006 (JP) 2006-149357

(51) Int. Cl. H01L 21/00

(52) U.S. Cl. 438/60

(57) ABSTRACT

A method of manufacturing a semiconductor multilayer structure having an interface between a first semiconductor layer and a second semiconductor layer includes forming the first semiconductor layer by introducing at least a first raw material gas into a reactor, forming a dummy layer including at least one of the elements constituting the second semiconductor layer by introducing at least a second raw material gas into the reactor, subsequent to the formation of the first semiconductor layer, removing the dummy layer by introducing an etching gas into the reactor, and forming the second semiconductor layer on the first semiconductor layer by introducing at least the second raw material gas into the reactor, after removing the dummy layer.

### BACKGROUND OF THE INVENTION

1. Field of the Invention

The present invention relates to a method of manufacturing a semiconductor multilayer structure such as a semiconductor laser device and, more particularly, to a semiconductor multilayer structure manufacturing method which realizes a sharp-profile interface.

2. Background Art

A semiconductor laser device has a semiconductor multilayer structure made of a compound. A semiconductor multilayer structure made of compounds of elements in the groups III and V is constituted by several semiconductor layers formed of combinations of elements such as In, Ga and Al in the group III and P and As in the group V.

As a method of manufacturing such a semiconductor multilayer structure, metalorganic chemical vapor deposition (hereinafter referred to as MOCVD) which is excellent in mass productivity is known (see, for example, Japanese Patent Laid-Open No. 62-183110). In MOCVD, organic metals such as trimethylindium (TMIn) and trimethylgallium (TMGa) and hydrogen compounds such as phosphine (PH₃) and arsine (AsH₃) are used as raw materials. These raw materials are gasified and supplied to a reactor. Thermal decomposition reaction of these raw materials is caused in the reactor to grow a semiconductor thin film on a substrate. The composition and the growth rate of the grown semiconductor are determined by the raw material supply rates and are controlled by opening/closing valves through which the raw materials are introduced into the reactor.

One of the problems with making a semiconductor multilayer structure is a problem with realization of a sharp-profile interface. For example, a group III-V compound semiconductor has a high ratio of group V materials such as PH₃ and AsH₃ and group III materials (V/III ratio) and requires supplying a raw material gas at a high rate into the reactor. When one layer in the semiconductor multilayer structure of this semiconductor is grown, the flow of a raw material gas cannot suitably follow the valve opening/closing, so that the raw material gas remains in the reactor. If residual elements in the gas are taken into an interface and the next different semiconductor layer, a sharp-profile heterointerface cannot be realized. A method has therefore been practiced in which the growth is interrupted when raw material gases are changed, and taking in of residual elements is limited by optimizing the amount of purge and purge time. However, it has been difficult to reliably prevent residual elements form being taken in. There have been also a problem that atoms in the outermost surface substitute for atoms in a purging atmosphere during growth interruption, and a problem that an impurity element in the purging atmosphere is taken and accumulated in the outermost surface (interface).

These are also problems with groups II, IV, and VI elements used as p-type and n-type impurities in doping and acting as the above-described residual elements as well as group V elements when a semiconductor multilayer structure is made. In particular, cyclopentadienyl magnesium (Cp₂Mg) or the like, which is a raw material in the case of doping with Mg, can easily remain in the reactor. For example, in a structure having an undoped layer on a doped layer, it was difficult to realize a sharp doping profile because a residual element was taken in the undoped layer.

### SUMMARY OF THE INVENTION

In view of the above-described problems, an object of the present invention is to provide a semiconductor multilayer structure manufacturing method which realizes a sharp-profile interface.

According to one aspect of the present invention, a method of manufacturing a semiconductor multilayer structure having an interface between a first semiconductor layer and a second semiconductor layer includes the steps of forming the first semiconductor layer by introducing raw material gas into a reactor, forming a dummy layer of all or part of elements constituting the second semiconductor layer by introducing raw material gas into the reactor subsequently to the formation of the first semiconductor layer, removing the dummy layer by introducing etching gas into the reactor, and forming the second semiconductor layer on the first semiconductor layer by introducing raw material gas into the reactor after removing the dummy layer.

According to the present invention, a semiconductor multilayer structure manufacturing method which realizes a sharp-profile interface can be obtained.

Other and further objects, features and advantages of the invention will appear more fully from the following description.

### BRIEF DESCRIPTION OF THE DRAWINGS

FIGS. 1-4 are sectional views for explaining a method of manufacturing a semiconductor multilayer structure according to First Embodiment of the present invention.

FIG. 5 is a diagram showing the results of comparison of the SIMS analysis As concentration profile of the InP/InGaAs heterointerface obtained by the manufacturing method of the present invention with that obtained by the conventional manufacturing method.

FIGS. 6-9 are sectional views for explaining a method of manufacturing a semiconductor multilayer structure according to Second Embodiment of the present invention.

FIGS. 10-13 are sectional views for explaining a method of manufacturing a semiconductor multilayer structure according to Third Embodiment of the present invention.

FIG. 14 shows the transition of the growth temperature, the growth of the InP layer and the AlInAs layer and removal by etching with respect to the growth time in Third Embodiment of the present invention.

FIGS. 15-18 are sectional views for explaining a method of manufacturing a semiconductor multilayer structure according to Fourth Embodiment of the present invention.

FIG. 19 shows the transition of the growth temperature, the growth of the InP layer and the AlInAs layer and removal by etching with respect to the growth time in Fourth Embodiment of the present invention.

### DETAILED DESCRIPTION OF THE PREFERRED EMBODIMENTS

### First Embodiment

A method of manufacturing a semiconductor multilayer structure according to First Embodiment of the present invention will be described with reference to the accompanying drawings. In this embodiment, a semiconductor multilayer structure having a heterointerface between an InGaAs layer (first semiconductor layer) and an InP layer (second semiconductor layer), which are compound semiconductor layers formed of different elements, is manufactured.

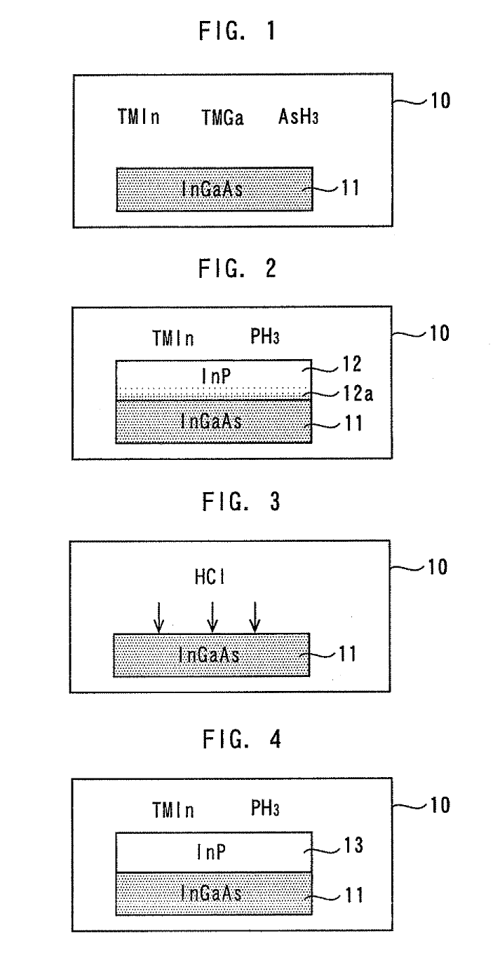

As shown in FIG. 1, raw material gases (TMIn, TMGa, AsH₃) are first introduced into a reactor 10 to form an InGaAs layer 11.

As shown in FIG. 2, subsequently to the formation of the InGaAs layer 11, raw material gases (TMIn, PH₃) are introduced into the reactor 10 to form a dummy layer 12 of InP. At this time, As is taken into a region close to the InP/InGaAs interface in the dummy layer 12 under the influence of AsH₃ remaining in the reactor 10, thereby forming a composition varied layer 12a (e.g., In₁₋ₓGaₓAs_{y}P_{1-y} layer (0≦x≦1, 0≦y≦1).

Subsequently, as shown in FIG. 3, HCl gas is introduced as etching gas into the reactor 10 to etch and remove the dummy layer 12 including the composition varied layer 12a. At this time, etching is performed in a V-group semiconductor material atmosphere for growing an InP layer afterward, i.e., a PH₃ atmosphere. The etching rate is controlled through the temperature in the reactor 10 or the flow rate of HCl gas. In this etching, a portion of the InGaAs layer 11 may be removed as well as the dummy layer 12. If a portion of the InGaAs layer 11 is removed, the thickness of the InGaAs layer 11 is set during growth by considering the portion to be removed.

Subsequently, as shown in FIG. 4, raw material gases (TMIn, PH₃) are introduced into the reactor 10 to form an InP layer 13 on the InGaAs layer 11. By the above-described process, a heterostructure of InP/InGaAs is manufactured.

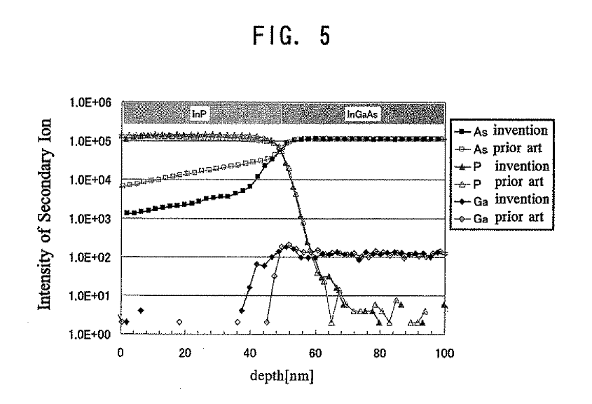

FIG. 5 is a diagram showing the results of comparison of the SIMS analysis As concentration profile of the InP/InGaAs heterointerface obtained by the manufacturing method of the present invention with that obtained by the conventional manufacturing method. As understood from the result, according to the present invention, a sharp concentration profile can be obtained compared to the conventional method.

Thus, according to this embodiment, a sharp-profile interface can be realized in manufacture of a semiconductor multilayer structure having a heterointerface between compound semiconductor layers formed of different elements.

This embodiment can be applied to manufacture of all other semiconductor heterostructures, e.g., AlInAs/InP, AlGaInP/GaAs and InP/AlInGaAs as well as to manufacture of the InP/InGaAs heterostructure. This embodiment can also be applied to manufacture of multilayer structures of group I-VII and group II-VI compound semiconductors as well as to manufacture of multilayer structures of group III-V compound semiconductors. Also, this embodiment can be applied to manufacture of any semiconductor multilayer structure other than the semiconductor laser structure.

It is not necessary that the dummy layer have the same constituent elements and composition ratio as those of the second semiconductor layer. A layer formed of all or part of the elements constituting the second semiconductor layer may suffice as the dummy layer. For example, if AlGaInP is grown as the second semiconductor layer, GaInP may be grown as the dummy layer.

### Second Embodiment

A method of manufacturing a semiconductor multilayer structure according to Second Embodiment of the present invention will be described with reference to the drawings. In this embodiment, a semiconductor multilayer structure having a heterointerface between an InP layer (first semiconductor layer) doped with Mg provided as an impurity and an undoped InGaAs layer (second semiconductor layer) is manufactured.

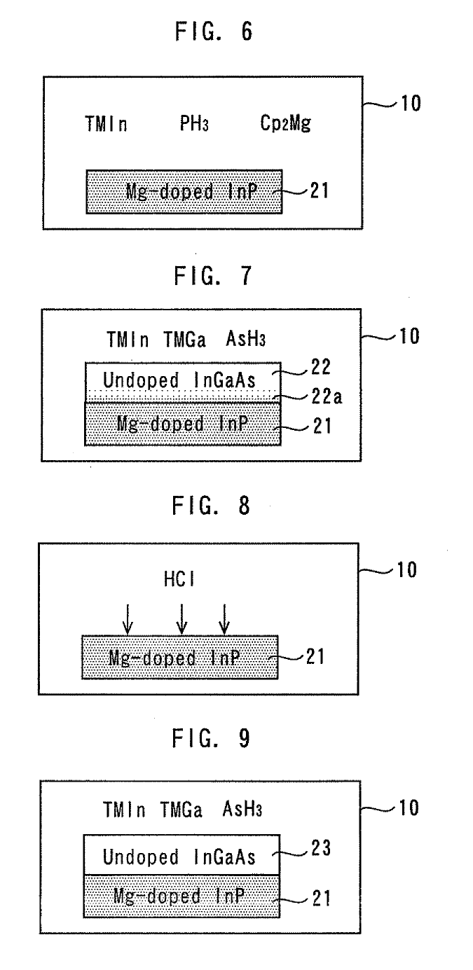

As shown in FIG. 6, a raw material gas (TMIn, PH₃) and Cp₂Mg provided as an Mg raw material are first introduced into a reactor 10 to form an Mg-doped InP layer 21.

As shown in FIG. 7, subsequently to the formation of Mg-doped InP layer 21, raw material gases (TMIn, TMGa, AsH₃) are introduced into the reactor 10 to form a dummy layer 22 of undoped InGaAs. At this time, a region 22a into which Mg is taken under the influence of Cp₂Mg remaining in the reactor 10 is formed in the dummy layer 22 close to the undoped InGaAs/Mg-doped InP interface.

Subsequently, as shown in FIG. 8, the crystal growth is interrupted and HCl gas is introduced as etching gas into the reactor 10 to etch and remove the dummy layer 22 including the region 22a into which Mg has been taken. At this time, etching is performed in a group V semiconductor material atmosphere for growing an InP layer afterward, i.e., an PH₃ atmosphere. The etching rate is controlled through the temperature in the reactor 10 or the flow rate of HCl gas. In this etching, a portion of the InP layer 21 may be removed as well as the dummy layer 22. If a portion of the InP layer 21 is removed, the thickness of the InP layer 21 is set during growth by considering the portion to be removed.

Subsequently, as shown in FIG. 9, raw material gases (TMIn, TMGa, AsH₃) are introduced into the reactor 10 to form an undoped InGaAs 23 on the Mg-doped InP layer 21. By the above-described process, a heterostructure of undoped InGaAs/Mg-doped InP is manufactured.

Thus, according to this embodiment, a sharp-profile interface can be realized in manufacture of a semiconductor multilayer structure having a heterointerface between a first semiconductor layer doped with an impurity and a second semiconductor layer undoped.

This embodiment can be applied to manufacture of all other semiconductor heterostructures, e.g., AlInAs/InP, AlGaInP/GaAs, InP/AlInGaAs and InGaAsP/InP as well as to manufacture of the InGaAs/InP heterostructure. This embodiment can also be applied to manufacture of homostructures of all compound semiconductors including undoped InP/Mg-doped InP as well as to manufacture of heterostructures. This embodiment can also be applied to manufacture of structures in which an undoped semiconductor layer is grown on a semiconductor layer doped with any element such as zinc (Zn), beryllium (Be), sulfur (S), silicon (Si), iron (Fe) or carbon (C) other than Mg. This embodiment can also be applied to manufacture of heterostructures and homostructures obtained by laminating layers doped with different types of elements such as A doped layer/B doped layer. This embodiment can be applied to manufacture of multilayer structures of group I-VII and group II-VI compound semiconductors as well as to manufacture of multilayer structures of group III-V compound semiconductors. Also, this embodiment can be applied to manufacture of any semiconductor multilayer structure other than the semiconductor laser structure.

It is not necessary that the dummy layer have the same constituent elements and composition ratio as those of the second semiconductor layer. A layer formed of all or part of the elements constituting the second semiconductor layer may suffice as the dummy layer. For example, if AlGaInP is grown as the second semiconductor layer, GaInP may be grown as the dummy layer.

### Third Embodiment

A method of manufacturing a semiconductor multilayer structure according to Third Embodiment of the present invention will be described with reference to the drawings. In this embodiment, a semiconductor multilayer structure having a heterointerface between an AlInAs layer (first semiconductor layer) and an InP layer (second semiconductor layer) grown at different temperatures is manufactured.

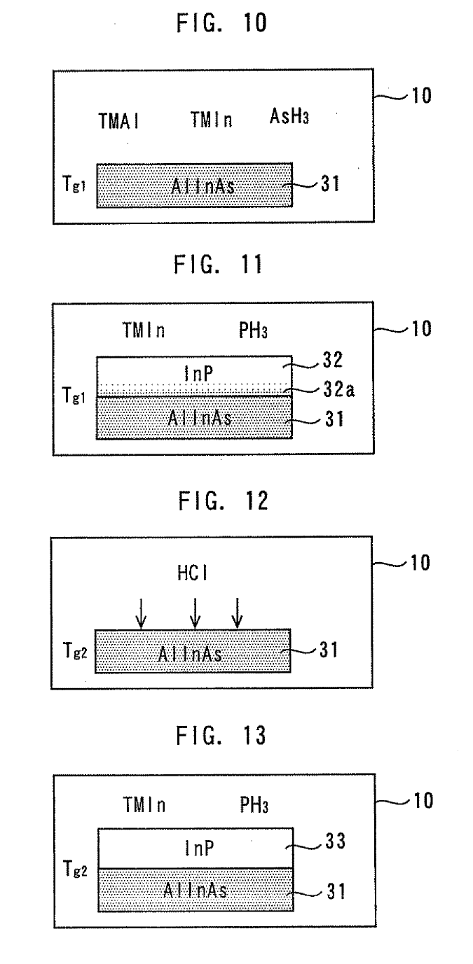

As shown in FIG. 10, raw material gases (TMAl, TMIn, AsH₃) are first introduced into a reactor 10 to form an AlInAs layer 31 at a growth temperature T_{g1} (first temperature).

As shown in FIG. 11, subsequently to the formation of the AlInAs layer 31, raw material gases (TMIn, PH₃) are introduced into the reactor 10 to form a dummy layer 32 of InP at the growth temperature T_{g1}. At this time, As is taken into a region close to the InP/AlInAs interface in the dummy layer 32 under the influence of AsH₃ remaining in the reactor 10, thereby forming a composition varied layer 32a (e.g., Al₁₋ₓInₓAs_{y}P_{1-y} layer (0≦x≦1,0≦y≦1). The growth temperature T_{g1} is not suitable as an InP growth temperature. Therefore the quality of the dummy layer 32 is not good.

Subsequently, as shown in FIG. 12, the temperature of the AlInAs layer 31 and the dummy layer 32 is reduced to a growth temperature T_{g2} (second temperature) at which an InP layer 33 to be formed afterward is grown. During interruption of crystal growth for this reduction in temperature, a group V semiconductor material atmosphere for growing the InP layer 33 afterward, i.e., a PH₃ atmosphere, is provided. HCl gas is then introduced as etching gas into the reactor 10 to etch and remove the dummy layer 32 including the composition varied layer 32a. At this time, etching is performed in the group V semiconductor material atmosphere for growing the InP layer 33 afterward, i.e., the PH₃ atmosphere. The etching rate is controlled through the temperature in the reactor 10 or the flow rate of HCl gas. In this etching, a portion of the AlInAs layer 31 may be removed as well as the dummy layer 32. If a portion of the AlInAs layer 31 is removed, the thickness of the AlInAs layer 31 is set during growth by considering the portion to be removed.

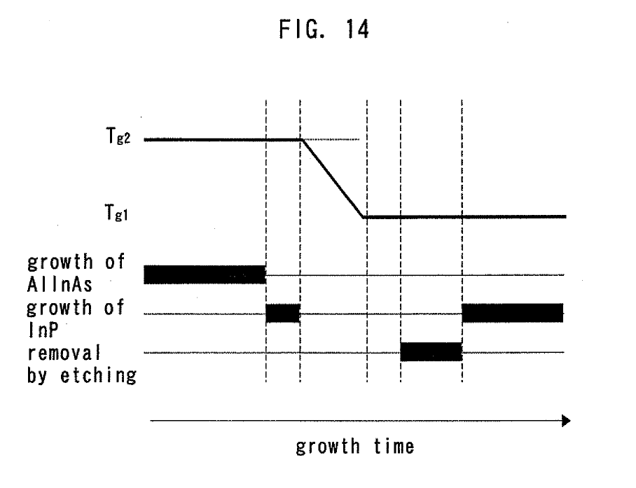

Subsequently, as shown in FIG. 13, raw material gases (TMIn, PH₃) are introduced into the reactor 10 to form the InP layer 33 on the AlInAs layer 31 at the growth temperature T_{g2}. The transition of the growth temperature, the growth of the InP layer and the AlInAs layer and removal by etching with respect to the growth time in this embodiment are as shown in FIG. 14. By the above-described process, a heterostructure of InP/AlInAs is manufactured.

Thus, according to this embodiment, a sharp-profile interface including no interface influenced by an atmosphere during growth interruption and a residual impurity can be realized in manufacture of a semiconductor multilayer structure having a heterointerface between first and second semiconductor layers grown at different temperatures.

This embodiment can be applied to manufacture of all other semiconductor heterostructures, e.g., AlGaInAs InP and AlGaInP/GaAs as well as to manufacture of the InP/AlInAs heterostructure. This embodiment can also be applied to manufacture of semiconductor homostructures as well as to manufacture of semiconductor heterostructures. This embodiment can also be applied to manufacture of multilayer structures of group I-VII and group II-VI compound semiconductors as well as to manufacture of multilayer structures of group III-V compound semiconductors. This embodiment can be applied to manufacture of semiconductor multilayer structures including in the crystal growth process execution of growth interruption for increasing the temperature and gas replacement as well as for reducing the temperature. Also, this embodiment can be applied to manufacture of any semiconductor multilayer structure in addition to the semiconductor laser structure.

It is not necessary that the dummy layer have the same constituent elements and composition ratio as those of the second semiconductor layer. A layer formed of all or part of the elements constituting the second semiconductor layer may suffice as the dummy layer. For example, if AlGaInP is grown as the second semiconductor layer, GaInP may be grown as the dummy layer.

### Fourth Embodiment

A method of manufacturing a semiconductor multilayer structure according to Fourth Embodiment of the present invention will be described with reference to the drawings. In this embodiment, a semiconductor multilayer structure having a heterointerface between an InP layer (first semiconductor layer) and an AlInAs layer (second semiconductor layer) grown at different temperatures is manufactured.

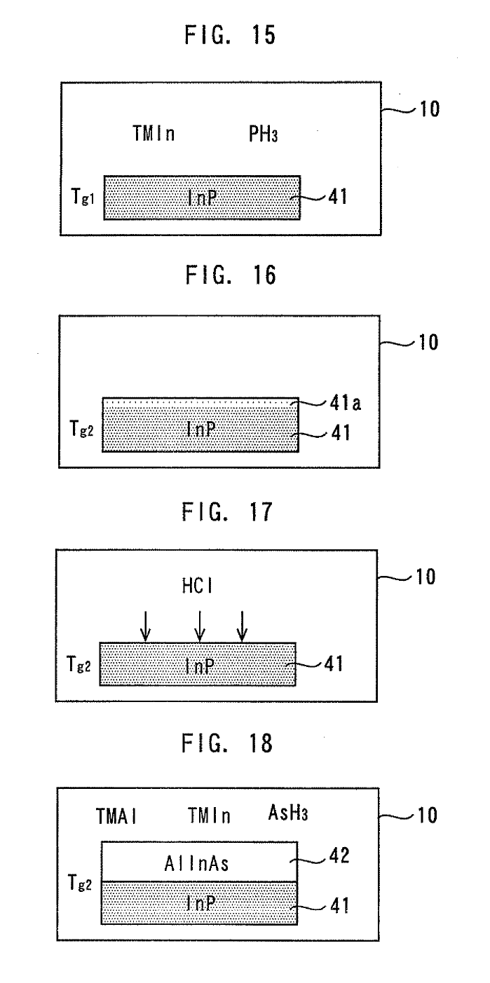

As shown in FIG. 15, raw material gases (TMIn, PH₃) are first introduced into a reactor 10 to form an InP layer 41 at a growth temperature T_{g1} (first temperature).

Subsequently, as shown in FIG. 16, the temperature of the InP layer 41 is increased to a growth temperature T_{g2} (second temperature) at which an AlInAs layer 42 to be formed afterward is grown. During interruption of crystal growth for this increase in temperature, a group V semiconductor material atmosphere for growing the AlInAs layer 42 afterward, i.e., an AsH₃ atmosphere, the PH₃ atmosphere at the time of growth of the InP layer 41 or a mixture of these atmospheres is provided. At this time, an outermost layer 41a of the InP layer 41 is exposed to an environment not suitable for InP growth. Therefore, desorption of P existing in the outermost layer, substitution of P for an element (e.g., As) in the atmosphere provided during growth interruption and accumulation on the surface of a residual impurity in the reactor 10, and so on occur, resulting in degradation of the quality of the outermost surface 41a of the InP layer 41.

Subsequently, as shown in FIG. 17, while the temperature of the InP layer 41 is set at the temperature T_{g2}, HCl gas is introduced as etching gas into the reactor 10 to etch and remove a surface portion of the InP layer 41 including the outermost surface 41a. At this time, etching is performed in the group V semiconductor material atmosphere for growing the AlInAs layer 42 afterward, i.e., the AsH₃ atmosphere. The etching rate is controlled through the temperature in the reactor 10 or the flow rate of HCl gas. The thickness of the InP layer 41 is set during growth by considering the portion to be removed.

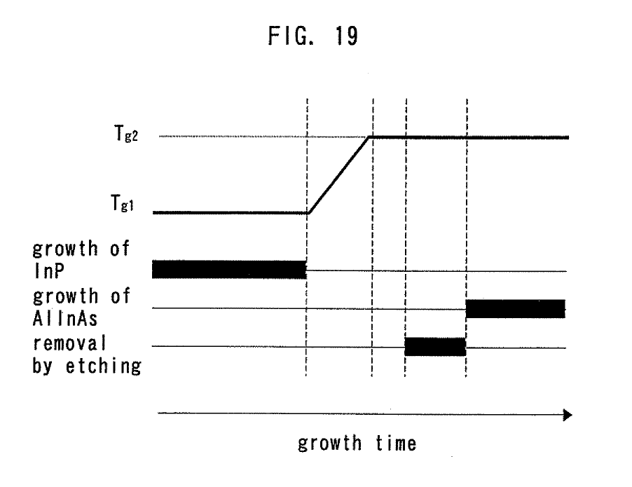

Subsequently, as shown in FIG. 18, raw material gases (TMAl, TMIn, AsH₃) are introduced into the reactor 10 to form the AlInAs layer 42 on the InP layer 41 at the growth temperature T_{g2}. The transition of the growth temperature, the growth of the InP layer and the AlInAs layer and removal by etching with respect to the growth time in this embodiment are as shown in FIG. 19. By the above-described process, a heterostructure of AlInAs/InP is manufactured.

Thus, according to this embodiment, a sharp-profile interface including no interface influenced by an atmosphere during growth interruption and a residual impurity can be realized in manufacture of a semiconductor multilayer structure having a heterointerface between first and second semiconductor layers grown at different temperatures.

This embodiment can be applied to manufacture of all other semiconductor heterostructures, e.g., AlGaInAs/InP and AlGaInP/GaAs as well as to manufacture of the AlInAs/InP heterostructure. This embodiment can also be applied to manufacture of semiconductor homostructures as well as to manufacture of semiconductor heterostructures. This embodiment can also be applied to manufacture of multilayer structures of group I-VII and group II-VI compound semiconductors as well as to manufacture of multilayer structures of group III-V compound semiconductors. This embodiment can be applied to manufacture of semiconductor multilayer structures including in the crystal growth process execution of growth interruption for reducing the temperature and gas replacement as well as for increasing the temperature. Also, this embodiment can be applied to manufacture of any semiconductor multilayer structure other than the semiconductor laser structure.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2006-149357, filed on May 30, 2006 including specification, claims, drawings and summary, on which the Convention priority of the present application is based, are incorporated herein by reference in its entirety.

1. A method of manufacturing a semiconductor multilayer structure having an interface between a first semiconductor layer and a second semiconductor layer, the method comprising:
forming the first semiconductor layer by introducing at least a first raw material gas into a reactor;
forming a dummy layer including at least one of the elements constituting the second semiconductor layer by introducing at least a second raw material gas into the reactor subsequent to the formation of the first semiconductor layer;
removing the dummy layer by introducing an etching gas into the reactor; and
forming the second semiconductor layer on the first semiconductor layer by introducing at least the second raw material gas into the reactor, after removing the dummy layer.

2. The method according to claim 1, wherein the first semiconductor layer and the second semiconductor layer are compound semiconductor layers formed of different elements.

3. The method according to claim 1, wherein the first semiconductor layer is a semiconductor layer doped with an impurity, while the second semiconductor layer is an undoped semiconductor layer.

4. The method according to claim 1, including forming the first semiconductor layer and the dummy layer at a first temperature; changing the temperature of the first semiconductor layer and the dummy layer to a second temperature when the dummy layer is removed; and forming the second semiconductor layer at the second temperature.

5. A method of manufacturing a semiconductor multilayer structure having an interface between a first semiconductor layer and a second semiconductor layer, the method comprising:
forming the first semiconductor layer at a first temperature by introducing at least a first raw material gas into a reactor;
changing the temperature of the first semiconductor layer to a second temperature after forming the first semiconductor layer;
removing a surface portion of the first semiconductor layer by introducing an etching gas into the reactor while maintaining the first semiconductor layer at the second temperature; and
forming the second semiconductor layer on the first semiconductor layer at the second temperature by introducing at least a second raw material gas into the reactor, after removing the surface portion of the first semiconductor layer.

6. The method according to claim 1, including using HCl gas as the etching gas.

7. The method according to claim 5, including using HCl gas as the etching gas.
